(19) United States
(12) Patent Application Publication
(10) Pub. No.: US 2025/0228032 A1
(43) Pub. Date: Jul. 10, 2025

(54) OMNIDIRECTIONAL SENSOR PACKAGE AND A METHOD FOR MAKING THE SAME

(71) Applicant: STATS ChipPAC Pte. Ltd., Singapore (SG)

(72) Inventors: BumRyul MAENG, Incheon (KR); JiSeon LEE, Incheon (KR); HyunKyu LEE, Incheon (KR); MyungHo JUNG, Gyeonggi-do (KR)

(21) Appl. No.: 19/008,657

(22) Filed: Jan. 3, 2025

(30) Foreign Application Priority Data
Jan. 5, 2024 (CN) 202410018189.0

(51) Int. Cl. H10F 39/95; H10F 39/10; H10F 71/00; H10F 77/00; H10F 77/50

(52) U.S. Cl. CPC H10F 39/95; H10F 39/107; H10F 71/134; H10F 71/136; H10F 77/50; H10F 77/933

(57) ABSTRACT

A sensor package comprises a first substrate and a second substrate. A first substrate sensor element is mounted on an inner surface of the first substrate and between the first substrate and the second substrate, and a second substrate sensor element is mounted on an inner surface of the second substrate and between the first substrate and the second substrate. A first side sensor element and a second side sensor element are mounted vertically between the first substrate and the second substrate, wherein the first and second side sensor elements have respective sensing areas facing away from each other and outwards of the sensor package, and wherein the first and second side sensor elements are electrically coupled to at least one of the first substrate and the second substrate. A first side clear mold and a second side clear mold are formed to cover the respective sensing areas of the first and second side sensor elements. An encapsulant layer is formed between the first substrate and the second substrate to encapsulate the first substrate sensor element, the second substrate sensor element and the first and second side sensor elements.

### TECHNICAL FIELD

The present application generally relates to semiconductor technologies, and more particularly, to an omnidirectional sensor package, and a method for making an omnidirectional sensor package.

### BACKGROUND OF THE INVENTION

Sensors are widely used in electronic devices to detect signals from exterior environment. Especially in real-time applications such as advanced driver assistance systems (ADAS), artificial intelligence systems and drones, sensors play an important role in providing reliable and accurate data for the overall system.

Conventional automotive sensors are generally unidirectional, and thus it is needed to adjust an angle of orientation for an automotive sensor to detect in all directions the environment of a vehicle where the automotive sensor is placed. For example, a rotation member or assembly composed generally of one or more motors, mirrors, and/or some other components is needed to rotate the automotive sensor in a horizontal plane, which, however, may increase the cost of manufacture as well as the size of the sensor.

Therefore, a need exists for further improvement to sensor devices.

### SUMMARY OF THE INVENTION

An objective of the present application is to provide a sensor device having an omnidirectional detection capability and a structure that can be easily implemented.

According to an aspect of the present application, there is provided a sensor package. The sensor package comprises: a first substrate having a first sensor opening passing therethrough, and a first substrate clear mold formed within the first sensor opening; a second substrate having a second sensor opening passing therethrough, and a second substrate clear mold formed within the second sensor opening, a first substrate sensor element mounted on an inner surface of the first substrate and between the first substrate and the second substrate, wherein the first substrate sensor element has a sensing area facing towards and aligned with the first sensor opening, and is electrically coupled to the first substrate; a second substrate sensor element mounted on an inner surface of the second substrate and between the first substrate and the second substrate, wherein the second substrate sensor element has a sensing area facing towards and aligned with the second sensor opening, and is electrically coupled to the second substrate; a first side sensor element and a second side sensor element mounted vertically between the first substrate and the second substrate, wherein the first and second side sensor elements have respective sensing areas facing away from each other and outwards of the sensor package, and wherein the first and second side sensor elements are electrically coupled to at least one of the first substrate and the second substrate; a first side clear mold and a second side clear mold covering the respective sensing areas of the first and second side sensor elements; and an encapsulant layer formed between the first substrate and the second substrate to encapsulate the first substrate sensor element, the second substrate sensor element and the first and second side sensor elements.

According to a further aspect of the present application, a method for making a sensor package is provided. The method comprises: providing a first substrate having a first sensor opening passing therethrough and a first substrate clear mold formed within the first sensor opening, wherein a first substrate sensor element is mounted on an inner surface of the first substrate and electrically coupled to the first substrate, and wherein the first substrate sensor element has a sensing area facing towards and aligned with the first sensor opening; mounting vertically a first side sensor assembly and a second side sensor assembly on the inner surface of the first substrate, wherein each of the first and second side sensor assemblies comprises a side sensor element having a sensing area facing outward and covered by a side clear mold, and wherein each of the first and second side sensor assemblies comprises a side encapsulant layer encapsulating the side sensor element but exposing the side clear mold; mounting a second substrate onto the first and second side sensor assembly such that the second substrate is supported by the side sensor elements; wherein the second substrate has a second sensor opening passing therethrough and a second substrate clear mold formed within the second sensor opening, a second substrate sensor element is mounted on an inner surface of the second substrate and electrically coupled to the second substrate, the second substrate sensor element has a sensing area facing towards and aligned with the second sensor opening; and wherein the side sensor elements of the first and second side sensor assemblies are electrically coupled to at least one of the first substrate and the second substrate; and forming a package encapsulant layer between the first substrate and the second substrate to encapsulate the first and second substrate sensor elements.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates a sensor package according to an embodiment of the present application.

FIG. 2 illustrates a sensor package according to another embodiment of the present application.

FIGS. 3A to 3E illustrate a method for making a sensor package according to an embodiment of the present application.

FIGS. 4A to 4H illustrate a sensor assembly according to an embodiment of the present application.

FIG. 5 illustrates another example of forming side interconnection structures such as the conductive blocks shown in FIG. 2.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As aforementioned, conventional sensor devices need to integrate therein a mechanical rotation assembly to equip the sensor device an omnidirectional detection capability. The mechanical rotation assembly is complicated in structure and increase the cost of manufacture. To address this issue, the inventors of the present application have conceived an invention of incorporating at least four sensor elements in a single sensor package, each of which can direct in a direction with respect to the sensor package and with a detection range greater than 90 degrees. In this way, the exterior environment of a system such as a vehicle which is mounted with the sensor package can be fully covered and detected by the sensor package. Furthermore, the at least four sensor elements can be integrated within the single sensor package using semiconductor packaging techniques, which is easily to implement and low in cost of manufacture.

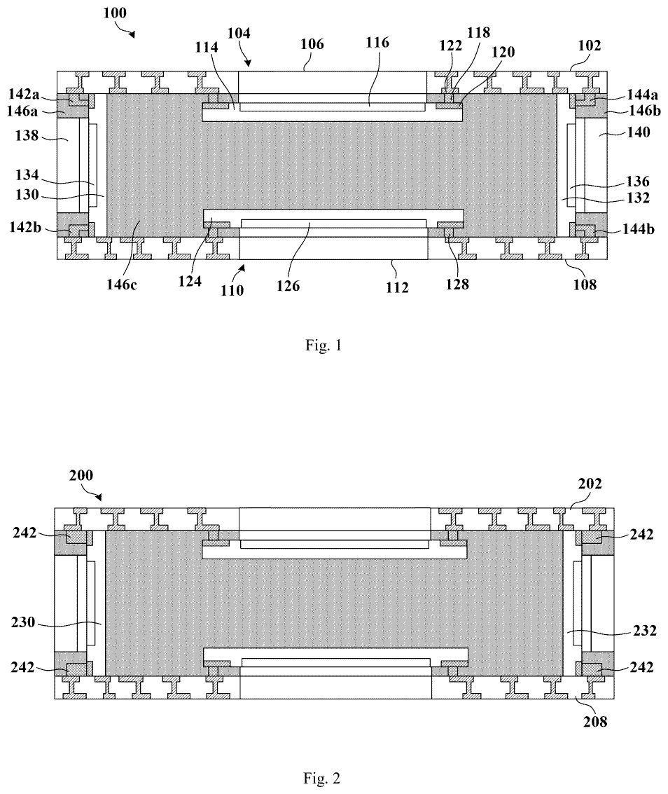

FIG. 1 illustrates a sensor package 100 according to an embodiment of the present application. As shown in FIG. 1, the sensor package 100 incorporates therein four sensor elements, each of which is exposed from a face of the sensor package 100 which may be shaped as a cube, for example. However, it can be appreciated that in some other examples two additional sensor elements may be integrated within the sensor package 100 and exposed from the other two faces of the cuboid sensor package 100. That is, each of all the six faces of the cuboid sensor package 100 may have a sensor element for detecting the environment outward of the package 100. Furthermore, in a case where the sensor package may be shaped as an octagonal prism with eight faces or any other polyhedrons, there may be sensor elements mounted at respective faces of the sensor package.

In some embodiments, the sensor elements integrated within the sensor package 100 may be optical sensors such as image sensors or infrared sensors which are sensitive to lights of certain specific wave lengths. In some other embodiments, the sensor elements may be ultrasonic sensors or other types of sensors which are sensitive to other types of waves that may propagate in an environment such as the ground environment, the underground environment or the undersea environment where a mechanical or electronic system equipped with such sensor package may be placed or travel. In a preferred embodiment, the sensor elements are formed using a semiconductor fabrication process to have a relatively compact structure. In some optional embodiments, when the sensor elements are formed using the semiconductor fabrication process, they may integrate therein circuits of other functionalities such as signal processing and data storage, and accordingly, the sensor elements can implement further calculation and signal processing based on the detected signals, reducing or avoiding the need to mount other types of semiconductor elements (e.g., a separate signal processing semiconductor chip implemented in form of application specific integrated circuit) in the sensor package 100. It would be appreciated that some other electronic components such as semiconductor chips may be integrated within the sensor package 100, as desired.

As shown in FIG. 1, the sensor package 100 includes a first substrate 102 having an outer surface and an inner surface which is opposite to the outer surface with respect to the first substrate 102. In particular, the first substrate 102 has a first sensor opening 104 passing therethrough, and a first substrate clear mold 106 which is formed within the first sensor opening 104. In the embodiment shown in FIG. 1, an outer surface is facing outward while an inner surface is facing inward with respect to the sensor package 100, but it is not required that the outer surfaces should be exposed from an outer surface of the entire sensor package 100. In some embodiments, the first substrate 102 may include a redistribution structure having one or more dielectric layers and one or more conductive layers between and through the dielectric layers. The conductive layers may define pads, traces and plugs through which electrical signals or voltages can be distributed horizontally and vertically across the redistribution structure. The first substrate 102 may include a plurality of outer conductive patterns formed on its outer surface and a plurality of inner conductive patterns formed on its inner surface. In addition, the redistribution structure may further include a plurality of conductive vias electrically connecting at least one of the outer conductive patterns with at least one of the inner conductive patterns. It could be appreciated that, the outer conductive patterns, the inner conductive patterns and the conductive vias may be implemented in various structures and types, but aspects of the present application are not limited thereto.

In the embodiment shown in FIG. 1, the first substrate 102 is at a top face of the cuboid sensor package 100 when viewed in the direction shown in FIG. 1. However, it is not required that the first substrate 102 should be always topmost the entire sensor package 100 in all applications or scenarios, for example when it is used in an electronic system. At a bottom face of the cuboid sensor package 100 which is opposite to the top face where the first substrate 102 is mounted, the sensor package 100 further includes a second substrate 108. The second substrate 108 may be symmetric to the first substrate 102 with respect to a horizontal plane that passes through a center of the sensor package 100. The inner surface of the first substrate 102 is facing towards an inner surface of the second substrate 108, while an outer surface of the second substrate 108 may be facing outward, and away from the first substrate 102. In some embodiments, the second substrate 108 may be formed of the same material(s) and structure as the first substrate 102, and optionally, have the same layout as the first substrate 102. For example, similar as the first substrate 102, the second substrate 108 may have a second sensor opening 110 passing therethrough, and a second substrate clear mold 112 which is formed within the second sensor opening 110. Both the first substrate clear mold 106 and the second substrate clear mold 112, and other clear molds according to the embodiments of the present application, may be formed of a molding material or encapsulant material that is transmissive to light.

A first substrate sensor element 114 is mounted on the inner surface of the first substrate 102, with its sensing area 116 facing towards the first sensor opening 104. In that case, the first substrate clear mold 106 may cover the sensing area 116 of the first substrate sensor element 114 and protect it from external environment and damages. The sensing area 116 may be aligned with the first sensor opening 104 and thus be further aligned with the first substrate clear mold 106 therein. Furthermore, since the first substrate clear mold 106 can be light-transparent or may otherwise enable the transmission of signals to be detected by the first substrate sensor element 114, the first substrate sensor element 114 can detect signals emitted from the environment as desired. In some embodiments where the first substrate sensor element 114 is an optical sensor, an optical filter layer may be formed between the first substrate clear mold 106 and the first substrate sensor element 114, and thus cover the sensing area 116 of the first substrate sensor element 114. Preferably, the optical filter layer includes an optical filter film, which may selectively allow light of a certain wavelength range (smaller/larger than a wavelength, within a wavelength range, at a wavelength, etc.) to pass through. For example, the optical filter film may be thin-film optical filters of alternating thin layers of materials with special optical properties. The optical filter film may transmit, block or reflect light of different wavelength ranges. The optical filter film can be a bandpass filter, a notch filter, a shortpass edge filter, a longpass edge filter, a dichroic filter or a customized filter matching arbitrary ranges of wavelengths. Preferably, the optical filter film may be formed via a coating process. It can be appreciated that the optical filter film may be any optical filter film that is suitable for filtering lights for an optical sensor. It can also be appreciated that the optical filter layer may include multiple filter layers having different optical properties.

The first substrate sensor element 114 is electrically coupled to the first substrate 102 to enable signal communication therebetween. For example, the first substrate sensor element 114 may send the detected signals (either after they are processed or not) to the first substrate 102 and further to an external device through the first substrate 102; and the first substrate sensor element 114 may further receive a control signal or other similar signals or instructions from the external device through the first substrate 102. In an embodiment, a plurality of interconnection structures 118 may be formed between the first substrate sensor element 114 and the first substrate 102, for example, to electrically couple conductive patterns or pads 120 and 122 formed on the first substrate sensor element 114 and on the first substrate 102. In this way, the first substrate sensor element 114 and the first substrate 102 can be electrically coupled with each other. It can be appreciated that the first substrate sensor element 114 may have a length greater than that of the first sensor opening 104 and thus extend laterally beyond the first sensor opening 104. As such, the sensing area 116 may occupy a portion (e.g., a central portion) of an outer surface of the first substrate sensor element 114, which is substantially at the same position as the first sensor opening 104, while the other portion of the outer surface of the first substrate sensor element 114 may not be formed as the sensing area, and can be used for the conductive patterns 120 and electrical connection with the interconnection structures 118. In some embodiments, the interconnection structures 118 may be solder bumps, metal posts or other conductive structures.

In some embodiments, the first substate clear mold 106 may have a thickness that is equal to or great than that of the first substrate 102, and alternatively, the first substrate clear mold 106 may have a thickness that is smaller than that of the first substrate 102. For example, when an optical filter layer is formed between the first substrate clear mold 106 and the first substrate sensor element 114, the optical filter layer may fill within the first sensor opening 104 along with the first substrate clear mold 106. In this way, the outer surface of the first substate sensor element 114 may be out of the first sensor opening 104, for example, when viewed in the vertical direction shown in FIG. 1.

As described above, the second substrate 108 and the components mounted thereon may have the same or similar configuration as the first substrate 102. In particular, a second substrate sensor element 124 may be mounted on an inner surface of the second substrate 108 and between the first and second substrates 102 and 108. The second substrate sensor element 124 may have a sensing area 126 facing towards the second sensor opening 110. As such, the sensing area 126 may be aligned with the second sensor opening 110 as well as the second substrate clear mold 112. The second substrate sensor element 124 may further extend laterally beyond the second sensor opening 110 to form at its lateral portions interconnection structures 128 that may electrically connect the second substrate sensor element 124 with the second substrate 108. Further details of the configuration of the second substrate 108 may be referred to the configuration of the first substrate and thus will not be elaborated herein.

Still referring to FIG. 1, the first substrate 102 and the components thereon are spaced apart from the second substrate 108 and the components thereon. A gap is formed between the first and second substrates 102 and 108. A first side sensor element 130 and a second side sensor element 132 are mounted vertically between the first substrate 102 and the second substrate 108, i.e., in the gap. The first side sensor element 130 and the second side sensor element 132 may have respective sensing areas 134 and 136 facing away from each other and outward of the sensor package 100. In this way, the sensing areas of the side sensor elements 130 and 132 can detect in two directions different from the directions of detection for the first and second substrate sensor elements 114 and 124, thereby implementing an omnidirectional detection capability for the sensor package 100. In some embodiments, the first and second side sensor elements 130 and 132 may have a same length in a direction vertical to the first and second substrates 102 and 108. As such, the first and second substrates 102 and 108 are generally parallel with each other, while the first and second side sensor elements are also generally parallel with each other.

The sensor package 100 further includes a first side clear mold 138 and a second side clear mold 140, which may cover the respective sensing areas 134 and 136 of the first and second side sensor elements 130 and 132 to protect them from external damages. Similar as the clear molds 106 and 112, the first and second side clear molds 138 and 140 may not block the transmission of signals to be detected by the first and second side sensor elements 130 and 132. In some embodiments where the side sensor elements 130 and 132 are optical sensors, respective optical filter layers may be formed between the side sensor element 130 or 132 and the side clear mold 134 or 136.

As the first and second side sensor elements 130 and 132 need to transmit the detected signals out and receive control signals or instructions, electrical connection and communication to the external device is needed. In order to realize the connection, specific side interconnection structures are formed between the first side sensor element 130 and/or the second side sensor elements 132 and the first substrate 102 and/or the second substrate 108. For example, as shown in FIG. 1, bonding wires 142a, functioning as the side interconnection structures, may be formed which connect conductive patterns or pads on an outer surface of the first side sensor element 130 and some of the conductive patterns on the inner surface of the first substrate 102, and/or bonding wires 142b may be formed which connect conductive patterns or pads on the outer surface of the first side sensor element 130 and some of the conductive patterns on the inner surface of the second substrate 108, so as to electrically couple the first side sensor element 130 with the first substrate 102 and/or the second substrate 108. Similarly, bonding wires 144a and 144b may be formed between the second side sensor element 132 and the first substrate 102 and/or the second substrate 108, to electrically couple them together. In this way, the first and second side sensor elements 130 and 132 can perform data and signal communication with the external device through at least one of the first and second substrates 102 and 108. It can be appreciated that in some optional embodiments, one of the side interconnect structures 142a and 142b may be omitted, and one of the side interconnect structures 144a and 144b may be omitted.

Furthermore, an encapsulant layer may be formed between the first substrate 102 and the second substrate 108 to encapsulate the first substrate sensor element 114, the second substrate sensor element 124, the first side sensor element 130 and the second side sensor element 132 and various other components or structure mounted between the first and second substrates 102 and 108. The encapsulant layer can integrate the sensor package 100 into a single piece and provide structural support and electrical isolation for the entire sensor package 100. In the embodiment shown in FIG. 1, the encapsulant layer may include three portions, i.e., a first portion 146a on the outer surface of the first side sensor element 130, a second portion 146b on the outer surface of the second side sensor element 132, and a third portion 146c between generally enclosed by the first and second side sensor elements 130 and 132 and the first and second substrates 102 and 108 (or the first and second substrate sensor elements 114 and 124). The first potion 146a may expose the first side clear mold 138, and the second portion 146b may expose the second side clear mold 140, to avoid blocking the transmission of signals to be detected through the side clear molds 138 and 140. In some embodiments, these portions 146a to 146c of the encapsulant layer may be formed separately in different molding steps, as will be elaborated below, but in some alternative embodiments, these portions 146a to 146c of the encapsulant layer may be formed in a single molding process. The encapsulant layer 146a to 146c may be made, partially or in all, of a polymer composite material such as epoxy resin with filler, epoxy acrylate with filler, or polymer with proper filler, using any suitable molding processes.

As can be seen from the embodiment shown in FIG. 1, the sensor package 100 have four sensor elements 114, 124, 130 and 132 at its four faces, each of which has a sensing area facing towards the external environment. These sensor elements 114, 124, 130 and 132 can operate simultaneously for purpose of detection, and thus there is no need to use a mechanical driving mechanism such as a mechanical rotation assembly to orientate the sensing areas to different spaces.

In the embodiment shown in FIG. 1, the bonding wires 142a, 142b, 144a and 144b may be L-shaped (for example, when viewed in a cross-section of the sensor package as shown in FIG. 1), to connect the conductive patterns on two surfaces that extend vertically to each other. In some alternative embodiments, the interconnection structures may be shaped in other forms to implement the electrical connection. FIG. 2 illustrates a sensor package 200 according to another embodiment of the present application, which has a set of different interconnection structures.

As shown in FIG. 2, respective conductive blocks 242 may be formed between a first substrate 202 and/or a second substrate 208, and a first side sensor element 230 and/or a second side sensor element 232. Each conductive block 242 has two surfaces that are in contact with one of the first and second substrates 202 and 208, and one of the first and second side sensor elements 230 and 232, respectively. It should be noted that the embodiment shown in FIG. 2 is a cross sectional view of the sensor package 200, and thus only one conductive block is shown at each intersection between the substrate(s) and the side sensor element(s). However, multiple conductive blocks may be arranged along the intersection between the substrate(s) and the side sensor element(s), to provide for multiple signal lines therebetween. It can be appreciated that the L-shaped bonding wires shown in FIG. 1 may similarly have multiple separate sections along the intersection of the substrate and the side sensor element.

The embodiments shown in FIGS. 1 and 2 both be formed as having a cuboid shape, and four faces of the cuboid sensor packages are formed with sensor elements that can detect the external environment, leaving the other two faces of the cuboid sensor packages unoccupied. As such, at least one of the unoccupied faces of the sensor packages may be used for mounting the sensor package onto an external device, for example, through solder bumps. In that case, interposers or e-bar blocks or other similar interconnection modules may be integrated within the sensor packages, to electrically extend the conductive patterns inside the sensor package, such as the conducive patterns formed on the inner surfaces of the first and second substrates, or even conductive patterns formed on inners surfaces of the first and second substrate sensor elements or on the first and second side sensor elements to the unoccupied faces of the sensor packages. For example, these interposers, e-bar blocks or interconnection modules may have L-shaped bonding wires similar as the bonding wires 142a, 142b, 144a and 144b shown in FIG. 1 or conductive blocks similar as the conductive blocks 242 shown in FIG. 2. However, it can be appreciated that in an alternative embodiment, the sensor packages may be mounted on an external device through one or both of the outer surfaces of the first and second substrates, as long as the detection of environment by the substrate sensor elements are not blocked by the external device.

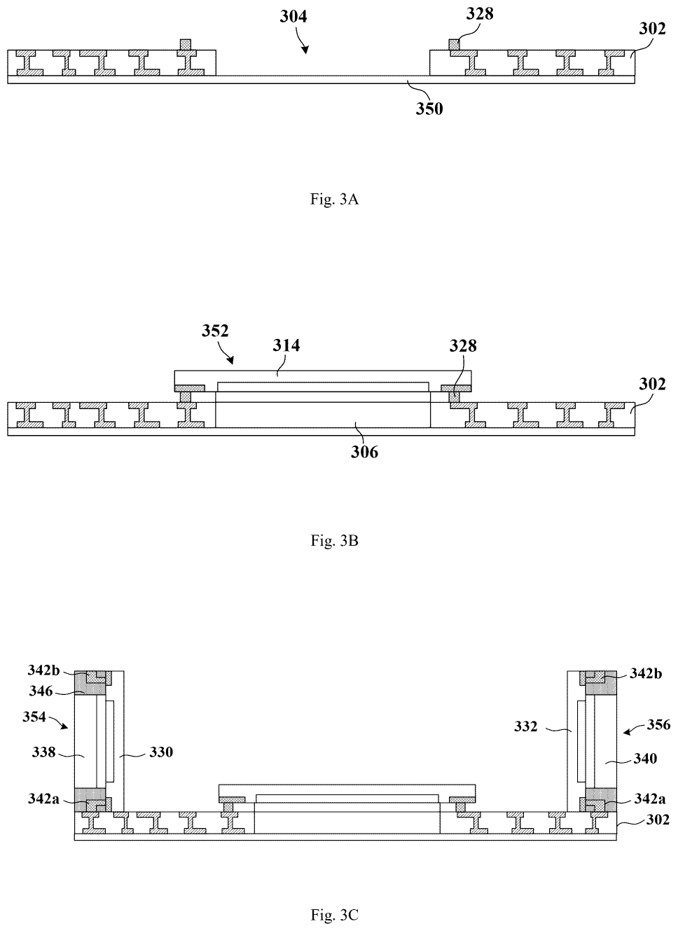

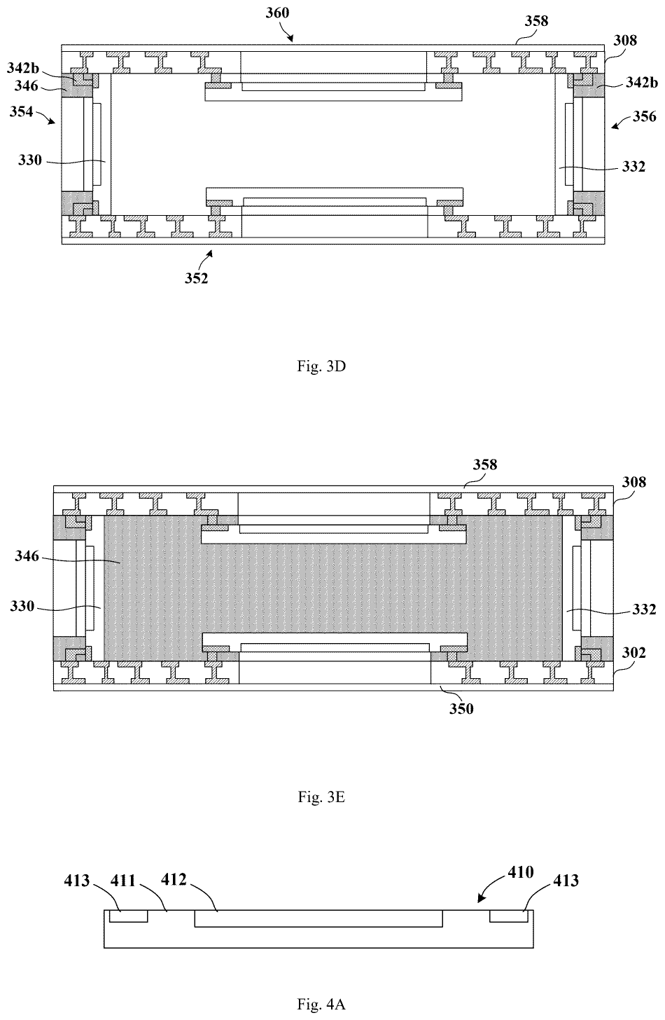

FIGS. 3A to 3E illustrate a method for making a sensor package according to an embodiment of the present application. The method may be used to make the sensor package 100 shown in FIG. 1. It can be appreciated that the method may be also used to make the sensor package 200 shown in FIG. 2, with slight modifications.

As shown in FIG. 3A, a first substrate 302 is provided. The first substrate 302 may be attached onto a carrier film 350 which can be releasably placed on a carrier such as a platform. It can be appreciated that FIGS. 3A to 3E only exemplarily illustrate a unit of the first substrate 302, which is corresponding to a sensor package to be formed. In practice, the first substrate 302 and other substrates may be shaped in a strip form, which can be processed together and later singulated into separated pieces after the packaging process is completed. Still referring to FIG. 3A, the first substrate 302 has a first sensor opening 304 which passes through the first substrate 302. The first sensor opening 304 is tentatively blocked by the carrier film 350, and thus can be filled with other structures as will be elaborated below. A set of interconnection structures 328 are also formed on an inner surface of the first substrate 302, which can be electrically connected with conductive patterns on the inner surface of the first substrate 302.

Next, as shown in FIG. 3B, a first substrate sensor assembly 352 is mounted on the first substrate 302. The first substrate sensor assembly 352 may be a smaller sensor package that is formed in advance. In particular, the first substrate sensor assembly 352 has a first substrate sensor element 314, and a first substrate clear mold 306 which can cover a sensing area of the first substrate sensor element 314 either directly or indirectly via an optical filter layer. The first substrate sensor element 314 has a footprint greater than the first substrate clear mold 306, and particularly extending laterally beyond four edges of the first substrate clear mold 306. As such, when the first substrate sensor assembly 352 is mounted on the first substrate 302, the first substrate clear mold 306 can be aligned with and formed within the first sensor opening 304, while the first substrate sensor element 314 may be supported by the interconnection structures 328 above the first substrate 302. The interconnection structures 328 are also connected with conductive patterns on an outer surface of the first substrate sensor element 314, thereby electrically coupling the first substrate 302 with the first substrate sensor element 314. In a preferred embodiment, the first substrate clear mold 306 may have a size that is substantially the same as that of the first sensor opening, and thus can be well fitted within the opening. In some embodiments where the first substrate clear mold 306 has a smaller size than the first sensor opening, an adhesive material such as a molding material may be further filled within the first sensor opening to form a tight sealing interface between the first substrate 302 and the first substrate clear mold 306. The molding material can be formed at this moment or later. As such, the sensing area of the first substrate sensor element 314 may face towards and be aligned with the first sensor opening in the first substrate 302.

Next, as shown in FIG. 3C, a first side sensor assembly 354 and a second side sensor assembly 356 may be mounted vertically on the inner surface of the first substrate 302. Each of the first and second side sensor assemblies 354 and 356 may include a side sensor element 330 or 332, which has a sensing area facing outward and covered by a side clear mold 338 or 340 either directly or indirectly via an optical filter layer. In particularly, the side sensor assemblies 354 and 356 may be mounted at two edges of the first substrate 302 in a back-to-back manner, to fully expose their respective sensing areas. In the embodiment, the first and second side sensor assemblies 354 and 356 both include a side encapsulant layer 346 which encapsulates the side sensor element 330 or 332 but exposes the side clear mold 338 or 340. The side encapsulant layer 346 may be formed with the side sensor assemblies 354 and 356 in advance. Furthermore, each of the first and second side sensor assemblies 354 and 356 has multiple bonding wires 342a that extend within the side encapsulant layer 346 and adjacent to the first substrate 302. The bonding wires 342a can be connected to the conductive patterns on the inner surface of the first substrate 302 and conductive patterns on the outer surface of the side sensor elements 330 or 332, so as to electrically couple the first substrate 302 with the side sensor element 330 or 332. In the embodiment, the bonding wires 342a are formed as an L-shaped structure, while in some other embodiments, the bonding wires 342a may be replaced with any other suitable interconnect structures such as the conductive blocks 242 shown in FIG. 2. Similarly, multiple bonding wires 342b are formed in the side encapsulant layer and adjacent to the edge of the side sensor elements 330 and 332 which is opposite to the first substrate 302, and the bonding wires 342b are exposed partially from the respective edges.

Next, as shown in FIG. 3D, a second substrate 308 may be mounted onto the first and second side sensor assemblies 354 and 356. In some embodiments, the second substrate 308 may be attached on a carrier film 358 which can be moved by a mechanical arm or carrier to place the second substrate 308 above the side sensor assemblies 354 and 356 and further onto them. As such, the second substrate 308 can be supported by the side sensor elements 330 and 332, as well as by the side encapsulant layer 346. By mounting the second substrate 308 on the side sensor assemblies 354 and 356, the interconnection structures 342b can be connected with conductive patterns formed on the second substrate 308. In this way, the second substrate 308 and the side sensor assemblies 354 and 356, or particularly, the side sensor elements 330 and 332, can be electrically coupled together through the interconnection structures 342b. The second substrate 308 may have a structure similar as the first substrate 302, and a second substrate sensor assembly 360 may be mounted on the second substrate 308, in a manner the same as or similar as the configuration of the first substrate sensor assembly 352 on the first substrate 302, which will not be elaborated herein. It can be appreciated that the second substrate sensor assembly 360 may be mounted on the second substrate 308 in advance, so that they can be mounted onto the side sensor assemblies 354 and 356 together.

Next, as shown in FIG. 3E, a package encapsulant layer 346 may be formed between the first substrate 302 and the second substrate 308 to encapsulate the first substrate sensor element and the second substrate sensor element that are mounted respectively on the first substrate 302 and the second substrate 308. The package encapsulant layer 346 can be in contact with the side sensor element 330 and 332, as is shown in FIG. 3E.

After the various steps shown in FIGS. 3A to 3E, the sensor package can be obtained. One of the carrier films 350 and 358 can be removed, and the other can be removed later from the sensor package after it is singlulated from the package strip where multiple units of packages are included.

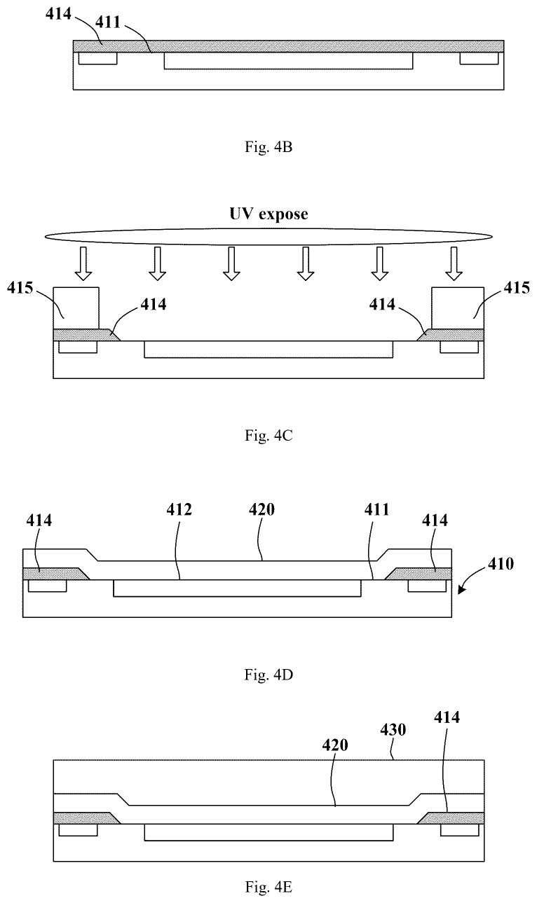

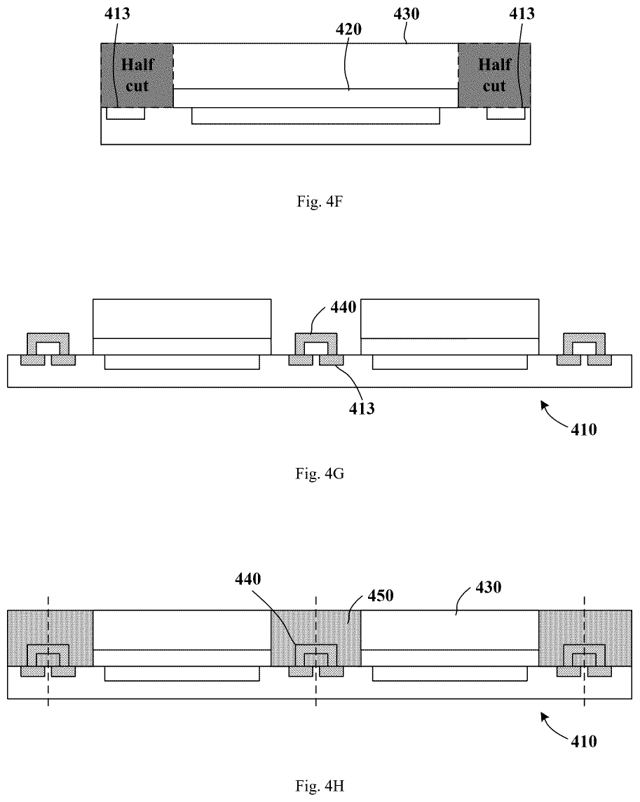

The substrate sensor assemblies and the side sensor assemblies may be formed in advance in a separate process. FIGS. 4A to 4H illustrate a method for forming a side sensor assembly. Some modifications may be made to the method shown in FIGS. 4A to 4H to form the substrate sensor assemblies, as desired.

As shown in FIG. 4A, a sensor element 410 is provided. The sensor element 410 includes a sensor front surface 411, and the sensor front surface 411 includes a sensing area 412 and a conductive pattern area 413. It can be appreciated that the sensor element 410 may not be individual sensor chips that have already been singulated from a sensor wafer. Rather, the sensor element 410 may be one sensor unit or cell formed in a sensor wafer, with other identical or similar sensor units or cells. That is, the method or at least most steps thereof may be implemented as a wafer level process.

A patterned photoresist layer is formed on the sensor front surface 411, and the patterned photoresist layer at least partially covers the conductive pattern area 413 of the sensor element 410 but exposes the sensing area 412. The patterned photoresist layer can be formed using an ultraviolet (UV) lithography process which is illustrated in FIGS. 4B and 4C. Specifically, as shown in FIG. 4B, the photoresist layer 414 fully covering the sensor front surface 411 is formed on top of the sensor front surface 411. For example, the photoresist layer 414 can be formed using printing, spin coating, or spray coating. Then the photoresist layer 414 is formed with certain pattern using such as a lithography process. For example, as shown in FIG. 4C, the photoresist layer 414 may be a positive photoresist layer, and a set of positions of the photoresist layer 414 desired to be remained may be covered or shielded by a mask 415 with a desired pattern. Then, the overall structure is exposed to UV light, and the exposed portions of the photoresist layer may be later removed with such as a developer while the covered portions of the photoresist layer may be remained after the development process. In some other embodiments, the photoresist layer may be a negative photoresist layer, and a mask covering the positions desired to be removed needs to be configured, which is exactly the opposite to the embodiment shown in FIG. 4C. Ideally, the edge of the photoresist pattern may be vertical to the covered surface. Yet in some cases, slopes may occur at the edge of the photoresist pattern owing to the gradual decrease of light intensity through absorption in photoresist during UV exposure, and the portion of photoresist closest to the surface is exposed by the highest intensity of light but and the bottom part is exposed at the least intensity. As such, upon photoresist development, the positive photoresist may give a positive slope of photoresist profile along the edge of the opening, as shown in FIG. 4C.

Further referring to FIG. 4D, at least one filter layer 420 is formed on top of the sensor front surface 411. The at least one filter layer 420 covers and is in direct contact with the sensing area 412 of the sensor element 410 and the patterned photoresist layer 414. Preferably, the at least one filter layer 420 fully covers the exposed portion of the sensing area 412 and the patterned photoresist layer 414.

Then, as shown in FIG. 4E, a clear molding layer 430 is formed on top of the at least one filter layer 420, wherein the clear molding layer 430 is transmissive to light to avoid undesired light screening for the sensor below. The clear molding layer 430 is used to form the clear molds as described with reference to the embodiment shown in FIGS. 1 and 2. Preferably, the clear molding layer 430 may entirely cover the at least one filter layer 420. Preferably, the clear molding layer 430 is configured to protect a sensor element underneath from external impact or damage. In addition, preferably, the clear molding layer 430 is transmissive to light without any filtering effect. It can be appreciated that a thickness of the photoresist layer 414, the at least one filter layer 420 and a thickness of the clear molding layer 430 may vary according to design and function of the present application.

Next, as shown in FIG. 4F, a portion of the clear molding layer 430, a portion of the at least one filter layer 420 and the patterned photoresist layer are removed, so as to at least partially expose the conductive pattern area 413. In some embodiments, the removal may adopt a half-cut process performed with a saw or a laser cutting tool. The position where the half-cut process is performed is configured such that the conductive pattern area 413 is at least partially exposed after the half-cut process. A depth of the half-cut process may be equal to or larger than a total thickness of the clear molding layer 430 and the at least one filter layer 420, yet smaller than the total thickness of the clear molding layer 430, the at least one filter layer 420 and the patterned photoresist layer. In some embodiments where the depth of the half-cut process is smaller than the total thickness of the clear molding layer 430, the at least one filter layer 420 and the patterned photoresist layer, some patterned photoresist layer is remained. In other words, the patterned photoresist layer may not be fully removed so that the remaining photoresist layer can protect the conductive pattern area thereunder from damage during the half-cut process. The remaining patterned photoresist layer may be removed later with a photoresist stripping process such as organic stripping, inorganic stripping or dry stripping.

After the steps shown in FIGS. 4A to 4F, sensor assemblies such as the substrate sensor assemblies 352 and 360 shown in FIG. 3D can be obtained. As the side sensor assemblies 354 and 356 shown in FIG. 3D may have some other structures, additional steps may be performed.

In particular, as shown in FIG. 4G, side interconnection structures such as bonding wires 440 may be formed on the front surface of the sensor element 410. In particular, when viewed in the wafer level, the side interconnections may extend between the conductive pattern areas 413 of each two adjacent sensor elements 410. The two adjacent sensor elements 410 may be formed in the same sensor wafer. For example, each of the side interconnection structures may be formed in a “n” shape. Next, as shown in FIG. 4H, an encapsulant layer 450 may be formed on the front surface of the sensor element 410 to fill the respective gaps between each two adjacent clear molds 430. The encapsulant layer 450 may encapsulate the bonding wires 440 to protect them from external damages. An excess encapsulant material formed on the clear molds 430 may be removed to expose the clear molds 430. Furthermore, a sawing process such may be performed to the encapsulant layer 450 to singulate the sensor assemblies from each other. The sawing process may separate the encapsulant layer 450 as well as the “n”-shaped bonding wires, thereby forming L-shaped bonding wires which have contact or pads exposed from the encapsulant layer 450. In this way, the side sensor assemblies 354 and 356 shown in FIG. 3D can be obtained.

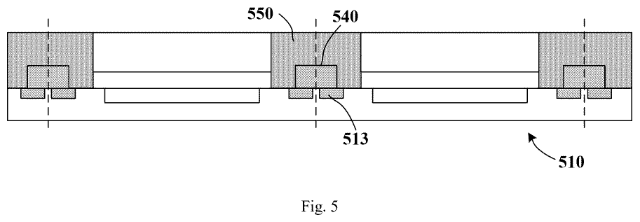

FIG. 5 illustrates another example of forming side interconnection structures such as the conductive blocks 242 shown in FIG. 2. As shown in FIG. 5, a set of wider conductive blocks 540 may be formed between each two sensor elements 510 and then encapsulated by an encapsulant layer 550. Next, the encapsulant layer 550 may be cut using a sawing process, to separate the wider conductive blocks 540 into two parts, each of which can be exposed from the encapsulant layer 550. In this way, conductive patterns 513 on a front surface of the sensor element 510 can be electrically coupled to the other conductive patterns through the exposed conductive blocks 540.

The discussion herein includes numerous illustrative figures that show various portions of an omnidirectional sensor package and a method for making such sensor package. For illustrative clarity, such figures do not show all aspects of each example sensor package. Any of the example packages provided herein may share any or all characteristics with any or all other packages provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A sensor package, comprising:
a first substrate having a first sensor opening passing therethrough, and a first substrate clear mold formed within the first sensor opening;
a second substrate having a second sensor opening passing therethrough, and a second substrate clear mold formed within the second sensor opening,
a first substrate sensor element mounted on an inner surface of the first substrate and between the first substrate and the second substrate, wherein the first substrate sensor element has a sensing area facing towards and aligned with the first sensor opening, and is electrically coupled to the first substrate;
a second substrate sensor element mounted on an inner surface of the second substrate and between the first substrate and the second substrate, wherein the second substrate sensor element has a sensing area facing towards and aligned with the second sensor opening, and is electrically coupled to the second substrate;
a first side sensor element and a second side sensor element mounted vertically between the first substrate and the second substrate, wherein the first and second side sensor elements have respective sensing areas facing away from each other and outwards of the sensor package, and wherein the first and second side sensor elements are electrically coupled to at least one of the first substrate and the second substrate;
a first side clear mold and a second side clear mold covering the respective sensing areas of the first and second side sensor elements; and
an encapsulant layer formed between the first substrate and the second substrate to encapsulate the first substrate sensor element, the second substrate sensor element and the first and second side sensor elements.

2. The sensor package of claim 1, wherein the first side sensor element and the second side sensor element are electrically coupled to both of the first substrate and the second substrate.

3. The sensor package of claim 2, wherein the first side sensor element and the second side sensor element are electrically coupled to both of the first substrate and the second substrate via respective L-shaped bonding wires or respective conductive blocks.

4. The sensor package of claim 1, wherein the encapsulant layer is such formed that the first and second side sensor elements are encapsulated by the encapsulant layer and the first and second side clear molds, wherein the first and second side clear molds are exposed from the encapsulant layer.

5. The sensor package of claim 1, wherein each of the respective sensing areas of the first substrate, second substrate, first side and second side sensor elements are covered by an optical filter layer.

6. The sensor package of claim 1, further comprising:
interconnection modules for electrically extending conductive patterns inside the sensor package to a face of the sensor package which is not occupied by any one of the substrate sensor elements and the side sensor elements.

7. The sensor package of claim 1, wherein the first and second side sensor elements have a same length in a direction vertical to the first and second substrates.

8. A method for making a sensor package, the method comprising:
providing a first substrate having a first sensor opening passing therethrough and a first substrate clear mold formed within the first sensor opening, wherein a first substrate sensor element is mounted on an inner surface of the first substrate and electrically coupled to the first substrate, and wherein the first substrate sensor element has a sensing area facing towards and aligned with the first sensor opening;
mounting vertically a first side sensor assembly and a second side sensor assembly on the inner surface of the first substrate, wherein each of the first and second side sensor assemblies comprises a side sensor element having a sensing area facing outward and covered by a side clear mold, and wherein each of the first and second side sensor assemblies comprises a side encapsulant layer encapsulating the side sensor element but exposing the side clear mold;
mounting a second substrate onto the first and second side sensor assembly such that the second substrate is supported by the side sensor elements; wherein the second substrate has a second sensor opening passing therethrough and a second substrate clear mold formed within the second sensor opening, a second substrate sensor element is mounted on an inner surface of the second substrate and electrically coupled to the second substrate, the second substrate sensor element has a sensing area facing towards and aligned with the second sensor opening; and wherein the side sensor elements of the first and second side sensor assemblies are electrically coupled to at least one of the first substrate and the second substrate; and
forming a package encapsulant layer between the first substrate and the second substrate to encapsulate the first and second substrate sensor elements.

9. The method of claim 8, wherein after mounting a second substrate onto the first and second side sensor assembly, the side sensor elements are electrically coupled to both of the first substrate and the second substrate.

10. The method of claim 9, wherein the side sensor elements are electrically coupled to both of the first substrate and the second substrate via respective L-shaped bonding wires or respective conductive blocks.

11. The method of claim 10, wherein the L-shaped bonding wires are formed using the following process:
forming “n”-shaped bonding wires between the side sensor element and another side sensor element which is adjacent to the side sensor element in a same sensor wafer;
forming an encapsulant layer between the side sensor element and another side sensor element to encapsulate the “n”-shaped bonding wires; and
cutting the encapsulant layer and the “n”-shaped bonding wires into two pieces to form the L-shaped bonding wires.

12. The method of claim 10, wherein the conductive blocks are formed using the following process:
forming conductive blocks between the side sensor element and another side sensor element which is adjacent to the side sensor element in a same sensor wafer;
forming an encapsulant layer between the side sensor element and another side sensor element to encapsulate the “n”-shaped bonding wires; and
cutting the encapsulant layer and the conductive blocks into two pieces so that each of the side sensor element and another side sensor element has respective portions of the conductive blocks.

13. The method of claim 8, wherein each of the respective sensing areas of the first and second substrate sensor elements and the first and second side sensor elements are covered by an optical filter layer.

14. The method of claim 8, wherein the method further comprises:
forming interconnection modules within the encapsulant layer to electrically extend conductive patterns inside the sensor package to a face of the sensor package which is not occupied by any one of the substrate sensor elements and the side sensor elements.

15. The method of claim 8, wherein the first and second side sensor elements have a same length in a direction vertical to the first and second substrates.
